(19) United States
(12) Patent Application Publication
(10) Pub. No.: US 2004/0150332 A1
(43) Pub. Date: Aug. 5, 2004

(54) Method for packaging organic electroluminescent components with polymer passivation layer and structure thereof

(75) Inventors: Chin-Pei Hwang, Kaohsiung City (TW); Jui-Ming Ni, Chu-Pei City (TW); Kuang-Jung Chen, Taipei City (TW); Hsueh-Wen Chen, Taichung Hsien (TW)

Correspondence Address: BIRCH STEWART KOLASCH & BIRCH, PO BOX 747, FALLS CHURCH, VA, 22040-0747, US

(73) Assignee: Windell Corporation

(21) Appl. No.: 10/625,592

(22) Filed: Jul. 24, 2003

Related U.S. Application Data
(62) Division of application No. 09/954,391, filed on Sep. 12, 2001, now abandoned.

(51) Int. Cl. H05B 33/00

(52) U.S. Cl. 313/512

(57) ABSTRACT

A method for packaging organic electroluminescent (EL) components with polymer passivation layer and structure thereof is developed on the basis of a multi-layer passivation concept to form a wet-adsorption polymer passivation layer for packaging and separating the EL components from moisture and oxygen by a coating or plating process, wherein a surface structure of cathode separators is also put into consideration for enhancement of the passivation layer which is then sealed to substitute for the conventional package-can design.

### FIELD OF THE INVENTION

This invention relates to a polymer passivation layer formed by way of spraying, screen-printing, dispensing or spincoating for protection of organic electroluminescent (EL) components disposed on a substrate in an organic light-emitting diode (OLED).

### BACKGROUND OF THE INVENTION

Package technology is one of the important factors to have the existing electroluminescent (EL) components been well protected. An EL component is generally multi-layer constructed, wherein the material in each layer is extremely sensitive to the external environments.

In order to facilitate infusion of electrons, a low-work function material is adopted for the cathode, however with a side effect of being oxidized easily that would degrade the component's function. Besides, a lighting layer formed by fluorescent organic solid material and an electrons transport layer and emitting materials layer are also extremely sensitive to humidity, oxygen, and some environmental factors, and any of which may render the organic substance crystallized to result in detachment of the organic material layer from the cathode to have the so-called “darkspot” phenomenon happened. Therefore, a conventional organic EL component can light only in a short lifetime if lacking a perfect package.

In order to prevent the organic EL component from being spoiled, a generic measure is taken by applying some binder of epoxy resin to the inner face of a panel in a component's package cover, and at this moment, the sealed portion is limited to the panel verge while dry nitrogen is sealed in the central hollow portion.

This measure does work to block moisture infiltration, however, the environment is still kept under highly humidified conditions to some extent on the other hand. When temperature goes higher and higher to reach 100° C. for example, the moisture remained on the substrate, the glass surface, or the package-can surface is supposed to invade into the package to enlarge the darkspot phenomenon. Some kind of desiccants, such as barium oxide or calcium chloride, is filled in the package cover for dissolving this problem so far, nevertheless, moisture will damage the EL component after the desiccants material is saturated and swollen, however.

In the schematic structure view of a conventional organic passive EL component shown in FIG. 1, an ITO (Indium-Tin oxide) anode layer 104 is disposed on a substrate 101, wherein a plurality of EL component's pixels 102 and cathode separators 103 are formed on the ITO anode layer 104, wherein a cathode layer 105 is formed on top of each pixel 102 and each rib 103; a polymer or an organic metallic material or layer 106 is filled in a gap between the pixels 102 and the ribs 103 or vapor-plated on each pixel 102 and rib 103; and finally, an inorganic or metallic protective layer 107, 108 and a polymer package layer 109 are laid one after another in sequence.

The cathode separators 103 are provided for eliminating cross talk, however, as uncountable step-like cavities and protrusions are formed between the organic metallic layer 106 and the cathode separators 103 to render the passivation package process difficult, hence, an intensively plated passivation structure without the conventional metallic or glass package-can is preferred for enhancing segregation of the organic EL component from moisture and oxygen and for facilitating an easy package and prolonging lifetime thereof.

The organic EL component and passivation thereof made by the prior art are regarded defective as the following:

1. Employed metallic or glass package-can for isolating external effects is relatively heavier and liable to be oxidized; the adhesion between metal and glass is rather poor; the juncture flatness is strictly requested; the unevenness of package stress will probably result in a detachment; the polymer binding material cannot prevent the moisture from invading thoroughly; and in the case barium oxide is adopted to serve as a desiccant, an environmental problem may arouse.

2. The polymer passivation layer is usually designed to serve for a polymer buffer layer between a metallic electrode and an inorganic layer, however because of its larger expansion coefficient than that of the metallic and the inorganic layer, a change in ambient air temperature will probably make the inside stress uneven and incur detachment of the polymer from the inorganic or the metallic layer.

3. A fair polymer passivation layer is generally not a wet-adsorbent layer, moisture can infiltrate through pin holes in the layer to reach and affect the component, and furthermore, if few water oozes through the cathode passivation material and the organic material that contact the polymer layer, moisture is then diffused inside to spoil the component.

In view of abovesaid defects of the prior art, this invention provides a method for packaging EL components and structure thereof by directly plating a passivation layer on the EL components for preventing water or oxygen from permeating so as to substitute for the conventional metallic or glass package-can to save the space, weight, and package alignment procedure.

The method of this invention is to: form an ITO anode layer on a transparent substrate of EL component; form an organic thin film on the anode layer by vapor plating or coating; form a low-work function cathode layer on the thin film; coat with polymer to form a layer by spraying, screen-printing, dispensing, or spincoating etc., in order to fill up the space between the component and cathode separators and provide a flat surface to avoid the “step effect” when masking and ensure tightness of a plated passivation layer for protection of the EL components.

Moreover, this invention further provides a passivation layer containing a polymer mixed with a filler agent for prevention of moisture infiltration and reduction of expansion coefficient of the passivation layer in order not to get peeled easily.

The merits of the passivation layer of this invention may be summarized in the following:

1. As the metallic or glass package-can is discarded, weight, thickness, and volume of this invention may be reduced or shrinked for application to an organic EL component disposed on a flexible substrate and to the portable 3C products.

2. The rugged surface between the cathode and the component is flatted and thereby to eliminate the “step effect” caused by change of temperature in a plated inorganic layer.

3. The usable polymer may include Epoxy, Acrylic, Urethane, Epoxy/Acrylic. Acrylic/Urethane, Silicone, Siloxane, Organic/Inorganic hybride. etc. The filler agent can be coated easily on the substrate for mass production by way of spraying, screen-printing, dispensing, or spincoating etc.

4. Wet-adsorbent substance is also added to have wet adsorbed in the polymer layers without diffusing to inside of the EL component to prolong the component's lifetime.

### SUMMARY OF THE INVENTION

The primary object of this invention is to provide a method for packaging organic electroluminescent components with polymer passivation layer and structure thereof developed on the basis of multi-layer passivation concept for separating the components from moisture and oxygen by a coating process, wherein a surface structure of cathode separators is also put into consideration for enhancement of the passivation layer which is then sealed to substitute for the conventional package-can design.

Another object of this invention is to use a polymer layer or a wet-adsorption polymer layer to form a passivation layer, wherein the wet-adsorption polymer layer will chemically adsorb moisture and retain it in order not to diffuse to inside of the components.

To realize abovesaid objects, in forming the passivation layer, the craggy surface of the organic EL component must be taken into consideration, which may cause detachment of the polymer layer from an inorganic layer or a metallic electrode. For getting rid of such a situation, this invention has provided a fabrication process suitable for mass production to form a passivation layer on a substrate by way of spraying, screen-printing, dispensing, or spincoating for preventing moisture from diffusing into the component's inside to lessen the possibility of spoilage accordingly.

For more detailed information regarding advantages or features of this invention, at least an example of preferred embodiment will be elucidated below with reference to the annexed drawings.

### BRIEF DESCRIPTION OF THE DRAWINGS

FIG. 1 shows a schematic structure of a conventional passive organic EL component.

FIG. 2 shows a schematic structure of an organic EL component of this invention;

FIGS. 3A through 3D illustrate a method for packaging organic EL components with a wet-adsorption polymer passivation layer; and

FIGS. 4A and 4B show mask patterns of this invention.

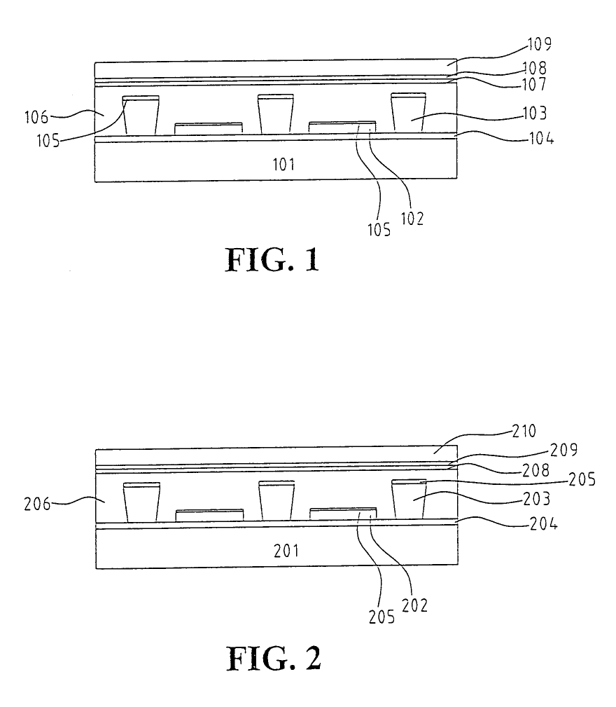

### DETAILED DESCRIPTION OF THE INVENTION

This invention is basically to provide a wet-adsorption polymer protective layer to substitute for a widely used passivation layer in a conventional organic electroluminescent (EL) component.

As illustrated in FIG. 2, an organic EL component in an embodiment of this invention mainly comprises a transparent substrate 201, at least a polymer passivation layer 206, and a polymer package layer 210.

On the transparent substrate 201, a plurality of pixels 202 and cathode separators 203, an anode layer of Indium-Tin oxide (ITO) 204 interfaced between the substrate 201 and the pixels 202, and a cathode layer 205 residing on the pixels 202 are disposed.

In the polymer passivation layer 206, a polymer or wet-adsorption polymer layer is directly formed to fill up the gaps between the pixels 202 and the cathode separators 203 and on the surface of the pixels 202 themselves. In addition, an inorganic layer 208 and a metallic layer 209 may be laid on the passivation layer 206 depending on requirements irrespective or the overlay order thereof.

The polymer package layer 210 is laid on the top surface to seal the passivation layer 206, the inorganic layer 208, and the metallic layer 209.

A wet-adsorption polymer protective layer of this invention for filling or covering the EL component comprises a polymer material containing at least a filler agent which is a wet-adsorbent or an inorganic material, wherein the addition ratio of the filler agent and the polymer material are 1˜90% respectively. An adsorption material of the filler agent is either a physical or a chemical wet-adsorbent material, wherein the grain size of the filler agent is about 0.1 mm˜10 μm while the chemical wet-adsorbent material should include at least one of the following compounds:

alkali metallic oxides, such as K₂O or Na₂O:

alkaline earth metallic oxides, such as CaO, BaO, or MgO;

sulfate compounds, such as Li₂SO₄, Na₂SO₄, MgSO₄, CoSO₄, Ga₂(SO₄)₃, Ti(SO₄)₂, or NiSO₄;

halogen metallic compounds, such as CaCl₂, MgCL₂, SrCl₂, YCl₂, CuCl₂, CsF, TaF₅, NbF₅, CaBr₂, CsBr₃, SeBr₄, VBr₂, MgBr₂, BaI₂, or MgI₂; or

perchlorate compounds, such as Ba(ClO₄)₂ or Mg(ClO₄)₂.

The filler agent is a low coefficient of thermal expansion material used for lowering the expansion coefficient of a polymer protective layer to approach that of an inorganic or a metallic layer so that the stress of the polymer layer with respect to the inorganic or the metallic layer can be eliminated effectively to avoid any possible detachment of the polymer protective layer. Besides, the sulfate compounds, the halogen metallic compounds, and the perchlorate compounds in the chemical adsorbent material would react on moisture and convert into crystalline water as shown in the following reaction equations from (1) to (4):

CaCl₂+6H₂O→CaCl₂.6H₂O (1)

CaSO₄+2H₂O→CaSO₄.2H₂O (2)

CuCl₂+2H₂O→CuCl₂.2H₂O (3)

MgSO₄+7H₂O→MgSO₄.7H₂O (4)

The alkali metallic oxides and the alkaline earth metallic oxides in the chemical adsorbent material would react on moisture and convert into hydroxides as shown in the following reaction equations frown (5) to (9):

K₂O+H₂O→2KOH (5)

Na₂O+H₂O→2NaOH (6)

BaO+H₂O→Ba(OH)₂ (7)

MgO+H₂O→Mg(OH)₂ (8)

CaO+H₂O→Ca(OH)₂ (9)

Moreover, the materials of the wet-adsorption polymer protective layer for packaging EL components may be a solvent or a nonsolvent thermo-curing or UV-curing monomer or oligomer, such as Epoxy, Acrylic, Urethane, Epoxy/acrylic, Acrylic/Urethane, Silicone, Silioxane, or Organic/inorganic hybrid, etc.

The coefficient of thermal expansion wet-adsorption polymer passivation layer of this invention is located in the range of 1˜100 ppm/° C., however, 5˜20 ppm/° C. is preferable. The wet-adsorption polymer protective layer is formed by spraying or screen-printing to overlay the EL component.

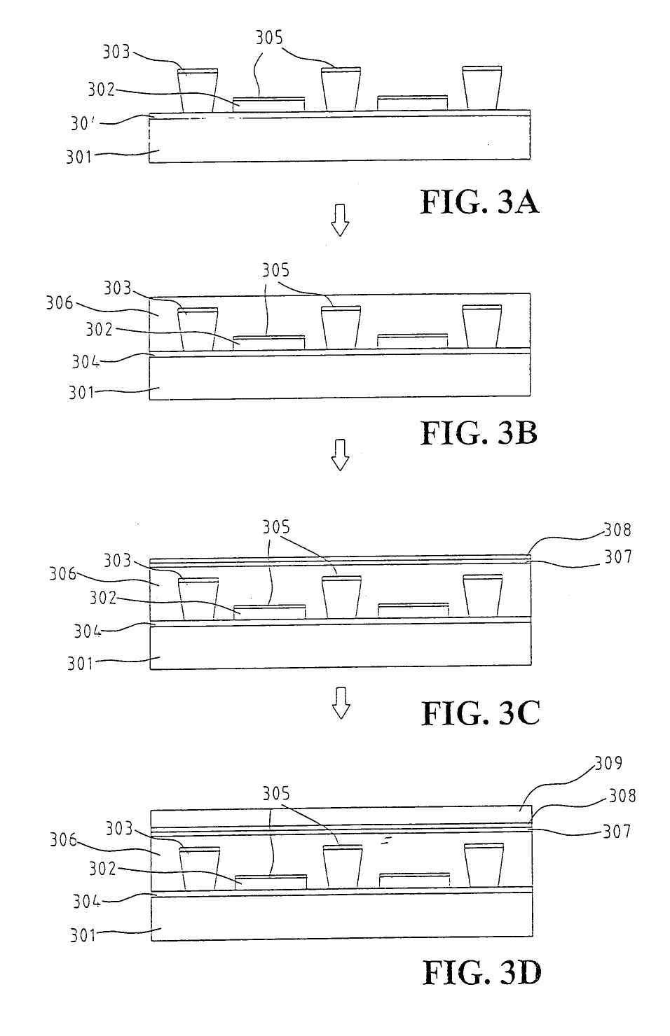

FIGS. 3A through 3D illustrate a method for packaging organic EL components with a wet-adsorption polymer passivation layer.

As shown in FIG. 3A, the method is to form on a substrate 301 a plurality of EL component's pixels 302 and cathode separators 303: an Indium-Tin oxide (ITO) anode layer 304 serving for an anode of the pixels 302; and a cathode layer 305 on the top surface of each pixel 302, wherein the cathode separators 303 are provided for prevention of “cross talk”.

Referring to FIG. 3B, the method is to apply a passivation layer 306 or up with at least a polymer sub-layer on abovesaid architecture to fill up the gaps between the pixels 302 and the cathode separators 303. The reason to form at least a polymer sub-layer is that because uncountable step-like cavities and protrusions are formed between the pixels 302 and the cathode separators 303 to render the passivation package process difficult. The polymer sub-layer is done by spraying, screen-printing, dispensing, or spincoating to form mask patterns for filling up the gaps mentioned and flatten the surface for eliminating the “step effect” of ensuing plating of a dielectric layer 307 or a metallic layer 308 so as to achieve a dense passivation structure shown in FIG. 3C.

The passivation layer should comprise at least: a wet-adsorption or inorganic filler agent, and a solvent or nonsolvent, thermo-curing or UV-curing, organic or inorganic polymer sub-layer. The thickness of the passivation layer should never be thinner than the height of the cathode separators and is controlled preferably between 1˜1000 μm.

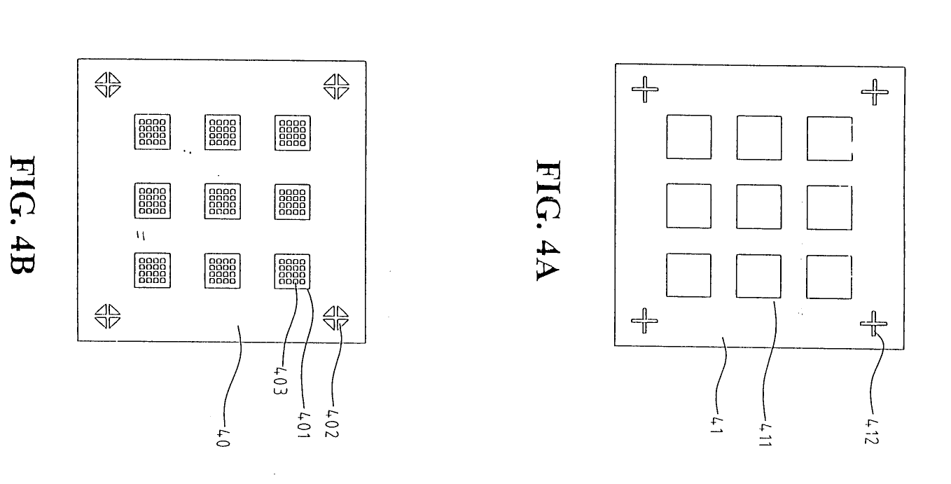

As shown in FIGS. 4A and 4B, a plurality of sprayed or screen-printed mask patterns 411 is the same with the EL component domains 401 formed on a substrate 40 in amount at corresponding positions, wherein each unit of the mask pattern 411 is slightly larger than each domain 401 in area; the alignment symbols 412 in the mask or screen 41 must be exactly aligned with the alignment symbols 402 in the substrate 40 when spraying or screen-printing; and the domains 401 comprise organic EL component's pixels 403 at least in thousands or up.

Finally, FIG. 3D shows a procedure for coating or sealing the entire passivation layer by overlaying the passivation layer 306, the dielectric layer 307, and the metallic layer 308 with a package material 309 which may be a thermo-curing or UV-curing package material of epoxy, acrylic, or silicon gel.

In the above described, at least one preferred embodiment has been described in detail with reference to the drawings annexed, and it is apparent that numerous variations or modifications may be made without departing from the true spirit and scope thereof, as set forth in the claims below.

What is claimed is:

1. A passivation layer for packaging organic electroluminescent (EL) components, the passivation layer being a polymer passivation layer or a wet-adsorption polymer passivation layer comprising
at least a wet-adsorption or an inorganic filler agent; and
at least a solvent or nonsolvent, thermo-curing or UV-curing polymer material:
wherein the filler agent is blended with a polymer material to form a wet-adsorption polymer protective layer for filling Up or overlaying the organic EL components.

2. The wet-adsorption polymer passivation layer according to claim 1, wherein the addition ratio of the filler agent and the high molecular material are 1˜90% respectively so as to produce the wet-adsorption polymer protective layer.

3. The wet-adsorption polymer passivation layer according to claim 1, wherein the polymer material is any of Epoxy, Acrylic, Urethane, Epoxy/Acrylic, Acrylic/Urethane, Silicone, Silioxane, or Organic/Inorganic hybrid.

4. The wet-adsorption polymer passivation layer according to claim 1, wherein a wet-adsorption material of the filler agent is either a physical or a chemical adsorption material; and the grain size of the filler agent is about 0.1 mm˜10 μm.

5. The wet-adsorption polymer passivation layer according to claim 4, wherein the chemical adsorption is at least a compound of the following: namely, an alkali metallic oxide, an alkaline earth metallic oxide, a sulfate compound, a halogen metallic compound, or a perchlorate compound.

6. The wet-adsorption polymer passivation layer according to claim 4, wherein the alkali metallic oxide is either K₂O or Na₂O.

7. The wet-adsorption polymer passivation layer according to claim 4, wherein the alkaline earth metallic oxide is CaO, BaO, or MgO.

8. The wet-adsorption polymer passivation layer according to claim 4, wherein the sulfate compound is Li₂SO₄, Na₂SO₄, MgSO₄, CoSO₄, Ga₂(SO₄)₃, Ti(SO₄)₂, or NiSO₄.

9. The wet-adsorption polymer passivation layer according to claim 4, wherein the halogen metallic compound is CaCl₂, MgCL₂, SrCl₂, YCl₂, CuCl₂, CsF, TaF₅, NbF₅, CaBr₂, CsBr₃, SeBr₄, VBr₂, MgBr₂, BaI₂, or MgI₂.

10. The wet-adsorption polymer passivation layer according to claim 4, wherein the perchlorate compound is either Ba(ClO₄)₂ or Mg(ClO₄)₂.

11. The wet-adsorption polymer passivation layer according to claim 1, wherein the thermal expansion coefficient of the passivation layer is located in the range of 1˜100 ppml/° C., however, 5˜20 ppm/° C. is preferable.

12. The wet-adsorption polymer passivation layer according to claim 1, which is formed by way of spraying, screen-printing, dispensing, or spincoating so as to fill up or overlay the EL components.

13. A method for packaging organic electroluminescent (EL) components with polymer passivation layer, comprising:
plating at least a wet-adsorption passivation layer on a flexible substrate made in glass, metal, or plastics;
forming a plurality of organic EL component's pixels and cathode separators on the substrate, wherein at least a sub-layer of the passivation layer is a polymer layer; and the passivation layer is applied to fill up the gaps between the pixels and the cathode separators; and
sealing the surface of the entire passivation layer by overlaying a package material thereon.

14. The method for packaging organic EL components according to claim 13, wherein the wet-adsorption passivation layer is composed of
a polymer material, which is a solvent or nonsolvent, thermo-curing or UV-curing, organic or Inorganic material; and
a filler agent, which is a wet-adsorption material or an inorganic material.

15. The method for packaging organic EL components according to claim 13, wherein the wet-adsorption passivation layer is formed by spraying, screen-printing, dispensing, or spincoating to produce a plurality of mask patterns for overlaying the EL components.

16. The method for packaging organic EL components according to claim 15, wherein the amount of mask pattern is equal to that of the EL component's domains; and each mask pattern is slightly larger than a paired off domain in area occupied at a correspondent position.

17. The method for packaging organic EL components according to claim 13, wherein the thickness of the polymer passivation layer should never be thinner than the height of the cathode separators and is controlled preferably between 1˜1000 μm.

18. The method for packaging organic EL components according to claim 13, wherein the package material is an Epoxy gel, an Acrylic gel, a Silicone gel, or any of various thermo-curing or UV-curing materials.

19. A package structure for organic EL components with polymer or wet-adsorption polymer passivation layer, comprising:
a flexible substrate made in glass, metal or plastics, having a plurality of organic EL component's pixels and cathode separators disposed thereon, an Indium-Tin oxide (ITO) anode layer formed between the substrate and the pixels to serve as an anode of the latter, wherein a cathode layer is laid on each pixel;
at least a polymer or a wet-adsorption polymer passivation layer being formed directly between the pixels and the cathode separators and on surface of the pixels; an optional inorganic or metallic layer being formed in an arbitrary order on top of the wet-adsorption polymer passivation layer depending on requirements; and
a polymer package layer for sealing the entire surface of the passivation layer, or the inorganic and/or the metallic layer if applied.
